(19) United States
(12) Patent Application Publication
(10) Pub. No.: US 2013/0095416 A1
(43) Pub. Date: Apr. 18, 2013

(54) PHOTOMASK AND PATTERN FORMATION METHOD

(71) Applicant: PANASONIC CORPORATION, Osaka (JP)

(72) Inventors: Yuji Nonami, Toyama (JP); Akio Misaka, Toyama (JP)

(73) Assignee: PANASONIC CORPORATION, Osaka (JP)

(21) Appl. No.: 13/691,142

(22) Filed: Nov. 30, 2012

Related U.S. Application Data
(63) Continuation of application No. PCT/JP2011/002241, filed on Apr. 15, 2011.

(30) Foreign Application Priority Data
Sep. 21, 2010 (JP) 2010-210672

(51) Int. Cl. G03F 1/00; G03F 7/20

(52) U.S. Cl. CPC G03F 1/00; G03F 7/2002; G03F 7/201
USPC 430/5; 430/325

(57) ABSTRACT

A photomask includes: a transparent substrate; and first and second mask patterns located on the transparent substrate and at least partially facing each other with a space sandwiched therebetween. The first mask pattern includes a semi-light-shielding part which transmits part of light therethrough and a light-shielding part. In the first mask pattern, the semi-light-shielding part at least partially faces the space with the light-shielding part sandwiched therebetween. In a direction along which the first mask pattern and the second mask pattern face each other, the first mask pattern has a size greater than (0.7×λ/NA)×M, and the space has a size less than or equal to (0.5×λ/NA)×M where λ is a wavelength of exposure light, NA is a numerical aperture of a reduced projection optical system of an exposure device, and M is a magnification of the reduced projection optical system.

### CROSS-REFERENCE TO RELATED APPLICATIONS

This is a continuation of PCT International Application PCT/JP2011/002241 filed on Apr. 15, 2011, which claims priority to Japanese Patent Application No. 2010-210672 filed on Sep. 21, 2010. The disclosures of these applications including the specifications, the drawings, and the claims are hereby incorporated by reference in their entirety.

### BACKGROUND

In recent years, miniaturization of circuit patterns has been more and more keenly needed to increase the integration degree of large-scale integrated (hereinafter referred to as LSI) circuits implemented by using semiconductors. Among these circuits, regarding transistor isolation, an LSI circuit includes both a fine dense pattern typified by, for example, static random access memories (SRAMs) and a fine isolated space pattern often observed in, for example, standard cells. To increase the integration degree of LSI circuits, it is important to miniaturize these two types of patterns at the same time.

Formation of a fine dense pattern employs off-axis illumination lithography, which is one of techniques called super-resolution lithography. This method is advantageous in forming a finer dense pattern, and increases the depth of focus (DOF) of periodically arranged dense patterns. However, off-axis illumination lithography does not increase the resolution for isolated space patterns, and disadvantageously, greatly reduces the DOF.

On the other hand, the use of a light source having a small interference degree in order to form a fine isolated space pattern makes it difficult to form a dense pattern.

As described above, optimum illumination conditions for an isolated space pattern are incompatible with optimum illumination conditions for a fine dense pattern. Thus, to form a fine dense pattern and a fine isolated space pattern at the same time, a light source with an interference degree of about 0.5-0.6 is used so that both a vertical incident component and an off-axis incident component of light from the light source are present.

In this case, however, the vertical incident component and the off-axis incident component are incompatible with each other, and thus it is difficult to achieve further miniaturization of a semiconductor device by miniaturizing a dense pattern and an isolated space pattern at the same time.

To solve this problem, the use of an auxiliary pattern as proposed in Japanese Patent Publication No. H07-140639 may be effective.

In the case of employing off-axis illumination to form a fine dense pattern, the DOF greatly decreases in a portion corresponding to an isolated space pattern. On the other hand, if an auxiliary pattern 31 is disposed near a main pattern 30 as illustrated in FIG. 15, the DOF in a portion corresponding to an isolated space pattern can be increased.

FIG. 16 is a graph showing the light intensity along the line XVI-XVI′ in FIG. 15 in the case of employing off-axis illumination for the pattern illustrated in FIG. 15. The auxiliary pattern 31 of a transmissive part having a size with which the auxiliary pattern 31 cannot be resolved is disposed near the main pattern 30 (corresponding to an isolated space pattern) of a transmissive part, and is exposed to light. Accordingly, as illustrated in FIG. 16, the light intensity has a periodicity of bright, dark, bright, dark, and bright, resulting in an increase in DOF in the isolated space pattern.

In this exposure, it is necessary to prevent the auxiliary pattern 31 from being transferred onto the wafer. In view of this, the auxiliary pattern 31 has a width smaller than that of the main pattern 30, i.e., less than or equal to the limit of resolution. In general, an auxiliary pattern is disposed in a rule-based manner. After disposing the auxiliary pattern, model-based optical proximity correction (OPC) is performed on a main pattern.

### SUMMARY

As described above, the auxiliary pattern needs to have a size less than or equal to the limit of resolution. However, with miniaturization of circuit patterns, the size of the auxiliary pattern necessary for obtaining a large DOF approaches the limit of resolution. In addition, the auxiliary pattern is disposed in a rule-based manner relative to a random pattern in, for example, a standard cell.

Accordingly, in some environments of the peripheral main pattern, the light intensity associated with the auxiliary pattern might exceed the threshold value at which transfer of the auxiliary pattern occurs. In this case, an unwanted pattern called a side lobe is formed on the wafer.

In addition, the auxiliary pattern needs to be smaller than the main pattern. However, as the main pattern itself is miniaturized to approach the limit of mask formation, it becomes more and more difficult to form a mask including an auxiliary pattern which needs to be smaller than the main pattern.

Further, a variation in size of the auxiliary pattern in the photomask greatly affects the size of the main pattern to be transferred. Thus, a mask including the auxiliary pattern needs to be formed accurately. However, since the size of the auxiliary pattern is currently small to a degree close to the limit of mask formation, it is difficult, and can be impossible, to accurately form a mask. Furthermore, inspection, for example, of the resultant mask becomes difficult, resulting in an increase in time necessary for forming a mask and cost for manufacturing masks.

In view of the foregoing facts, a photomask which can increase the DOF and can reduce formation of a side lobe in a transferred pattern and a pattern formation method (especially a method for forming an isolated space pattern in the case of employing off-axis illumination to form a fine dense pattern) using the photomask will be described hereinafter.

Inventors of the present disclosure variously studied a method for increasing the DOF and reducing formation of a side lobe without using an auxiliary pattern of a transmissive part as described above. After the study, the inventors came to have the idea of using a semi-light-shielding part which transmits part of exposure light therethrough in order to provide a periodicity such as bright, dark, bright, and dark, in distribution of the light intensity in exposure with a photomask.

Specifically, a first photomask according to the present disclosure includes: a transparent substrate; and first and second mask patterns located on the transparent substrate and at least partially facing each other with a space sandwiched therebetween, wherein the first mask pattern includes a semi-light-shielding part which transmits part of light therethrough and a light-shielding part, in the first mask pattern, the semi-light-shielding part at least partially faces the space with the light-shielding part sandwiched therebetween, in a direction along which the first mask pattern and the second mask pattern face each other, the first mask pattern has a size greater than (0.7×λ/NA)×M, and the space has a size less than or equal to (0.5×λ/NA)×M (where λ is a wavelength of exposure light, NA is a numerical aperture of a reduced projection optical system of an exposure device, and M is a magnification of the reduced projection optical system).

In this photomask, in the direction along which the first mask pattern and the second mask pattern face each other, the semi-light-shielding part of the first mask pattern, the light-shielding part of the first mask pattern, the space, and the second mask pattern are arranged in this order. Accordingly, in distribution of the light intensity associated with these parts is allowed to have a periodicity such as bright, dark, bright, and dark in exposure, thereby increasing the DOF. In particular, when off-axis illumination is employed to form a fine dense pattern, the DOF in the space can also be increased, unlike the case of a binary mask including no semi-light-shielding part. As a result, both types of patterns can be appropriately formed.

The light transmittance of the semi-light-shielding part can be set such that light transmitted through the semi-light-shielding part has a light intensity at which reaction of, for example, a resist does not occur (i.e., no exposure region is formed). This structure can reduce formation of an unwanted pattern (e.g., a side lobe) from the semi-light-shielding part provided to increase the DOF. In addition, the semi-light-shielding part and the light-shielding part of the first mask pattern can be made larger than the limit of mask formation. That is, the photomask can be more easily formed.

The second mask pattern may include a light-shielding part, and in a direction along which the first mask pattern and the second mask pattern face each other, the second mask pattern may have a size less than or equal to (0.7×λ/NA)×M.

In a case where a portion of the second mask pattern facing the first mask pattern with the space sandwiched therebetween has a small size, the second mask pattern is made of the light-shielding part and is formed to have the above-described size. Then, the DOF can be increased in each of the patterns.

The second mask pattern may include a semi-light-shielding part which transmits part of light therethrough and a light-shielding part, and in the second mask pattern, the semi-light-shielding part may face the space with the light-shielding part sandwiched therebetween.

In this structure, the semi-light-shielding part of the first mask pattern, the light-shielding part of the first mask pattern, the space, the light-shielding part of the second mask pattern, and the semi-light-shielding part of the second mask pattern are arranged in this order. Accordingly, in distribution of the light intensity in exposure, a periodicity such as bright, dark, bright, dark, and bright can be obtained. As a result, the DOF can be increased.

In a direction along which the first mask pattern and the second mask pattern face each other, the second mask pattern may have a size greater than (0.7×λ/NA)×M.

In a case where a portion of the second mask pattern facing the first mask pattern with the space sandwiched therebetween has a large size, the second mask pattern is formed to include the light-shielding part and the semi-light-shielding part and have the above-described size. Then, the DOF can be increased in each of the patterns.

In a direction along which the first mask pattern and the second mask pattern face each other, a size of the light-shielding part and a size of the semi-light-shielding part may be determined based on λ, Na, and M (where λ is a wavelength of exposure light, NA is a numerical aperture of a reduced projection optical system of an exposure device, and M is a magnification of the reduced projection optical system).

The foregoing parameters are examples of parameters for determining the sizes of the light-shielding part and the semi-light-shielding part.

The light-shielding part may have a size greater than or equal to (0.13×λ/NA)×M.

This structure can obtain a sufficient margin of the exposure amount in exposure with the photomask.

The light-shielding part may have a size less than or equal to (1.13×λ/NA)×M.

This structure can significantly increase the DOF.

The semi-light-shielding part may have a size greater than or equal to (0.42×λ/NA)×M.

This structure can significantly increase the DOF.

The photomask may have a structure in which light transmitted through the semi-light-shielding part has a phase identical to that of light transmitted through the space.

This structure can allow the patterns to be more appropriately exposed to light.

The light-shielding part may surround the semi-light-shielding part.

This structure can provide a periodicity such as bright, dark, and bright in distribution of the light intensity in exposure in any direction in the mask pattern.

A width of the light-shielding part at a projecting corner of the first mask pattern may be larger than that at a recessed corner of the first mask pattern.

This structure ensures a desired exposure pattern especially of the shape of a corner because of optical proximity correction.

The semi-light-shielding part may be divided into a plurality of portions by the light-shielding part.

The light-shielding part may be partially sandwiched between the semi-light-shielding parts of the first and second mask patterns in a direction along which the first mask pattern and the second mask pattern face each other.

This structure can further enhance a periodicity such as bright, dark, and bright in distribution of the light intensity in exposure by using the light-shielding part and the semi-light-shielding part.

The semi-light-shielding part may have a light transmittance with which an intensity of light transmitted through the semi-light-shielding part is lower than that at which an exposure region is formed.

Then, it is possible to reduce formation of an unwanted pattern by light transmitted through the semi-light-shielding part in exposure.

The semi-light-shielding part may be located only in a region facing the space with the light-shielding part sandwiched therebetween.

This structure can increase the DOF in a necessary portion, and in addition, reduce the mask cost by easing formation of the photomask, thereby reducing the time necessary for drawing.

A second photomask according to the present disclosure includes: a reflective substrate; and first and second mask patterns located on the reflective substrate and at least partially facing each other with a space sandwiched therebetween, wherein the first mask pattern includes a semi-reflective part which reflects part of light and a non-reflective part which reflects substantially no light, in the first mask pattern, the semi-reflective part faces the space with the non-reflective part sandwiched therebetween, in a direction along which the first mask pattern and the second mask pattern face each other, the first mask pattern has a size greater than (0.7×λ/NA)×M, and the space has a size less than or equal to (0.5×λ/NA)×M (where λ is a wavelength of exposure light, NA is a numerical aperture of a reduced projection optical system of an exposure device, and M is a magnification of the reduced projection optical system).

This second photomask is implemented as a reflective photomask having the same or similar advantages as those of the first photomask which is a transmissive photomask. Advantages of the second photomask can be understood by replacing the transparent substrate of the first photomask by the reflective substrate, the semi-light-shielding part of the first photomask by the semi-reflective part, the light-shielding part of the first photomask by the non-reflective part, transmission (or pass) of the first photomask by reflection, and light transmittance of the first photomask by light reflection factor, for example,

A pattern formation method according to the present disclosure uses one of the first photomask or the second photomask, and includes forming a resist film on a substrate; irradiating the resist film with exposure light through the photomask; and developing the resist film irradiated with the exposure light, and then patterning the resist film.

In this pattern formation method, it is possible to reduce formation of an unwanted pattern in exposure, while increasing the DOF. Consequently, in particular, in the case of employing off-axis illumination to form a a fine dense pattern, the DOF in an isolated space pattern can be increased. As a result, each of the patterns can be appropriately formed.

The irradiating the resist film may employ off-axis illumination.

Then, the patterns can be more appropriately formed.

As described above, the photomasks and the pattern formation methods using these photomasks enable accurate formation of patterns without formation of a side lobe, and can ease formation of the photomasks. In particular, the present disclosure is advantageous especially in forming both a fine dense pattern and an isolated space pattern with off-axis illumination, and a fine semiconductor device can be fabricated.

### BRIEF DESCRIPTION OF THE DRAWINGS

FIGS. 1A-1C schematically illustrate an example pattern according to an embodiment of the present disclosure, a structure of an example photomask for use in formation of the example pattern in plan view, and a cross-sectional structure of the example photomask taken along the line Ic-Ic′.

FIG. 2 schematically illustrates distribution of the light intensity in exposure with the photomask illustrated in FIGS. 1B and 1C.

FIG. 3 shows changes in CD with respect to focus variations in the example photomask of the embodiment and a comparative photomask.

FIG. 4 shows a relationship between the width of a light-shielding part and a DOF in an isolated space in the example photomask of the embodiment.

FIG. 5 shows a relationship between the width of a light-shielding part and a NILS in an isolated space pattern in the example photomask of the embodiment.

FIG. 6 shows a relationship between the width of a semi-light-shielding part and a DOF obtained by simulation in the example photomask of the embodiment.

FIGS. 7A-7D schematically illustrate a pattern formation method using the example photomask of the embodiment.

FIGS. 8A-8D schematically illustrate an example pattern according to a variation of the embodiment, and a structure in plan view, a cross-sectional structure taken along the line VIIIc-VIIIc′, and a cross-sectional structure taken along the line VIIId-VIIId′ of an example photomask for use in formation of the example pattern.

FIGS. 9A and 9B schematically illustrate a structure in plan view and a cross-sectional structure taken along the line IXb-IXb′ of another example photomask for use in formation of the example pattern illustrated in FIG. 1A.

FIG. 10 schematically illustrates distribution of the light intensity in exposure with the photomask illustrated in FIGS. 9A and 9B.

FIG. 11 schematically illustrates a structure in plan view of yet another example photomask for use in formation of the example pattern illustrated in FIG. 1A.

FIG. 12 schematically illustrates a structure in plan view of still another example photomask for use in formation of the example pattern illustrated in FIG. 1A.

FIG. 13 illustrates another example of a cross-sectional structure of the example photomask of this embodiment illustrated in FIG. 1C.

FIG. 14 illustrates yet another example of a cross-sectional structure of the example photomask of this embodiment illustrated in FIG. 1C.

FIG. 15 illustrates a structure in plan view of a conventional photomask.

FIG. 16 schematically shows distribution of the light intensity in exposure with the photomask illustrated in FIG. 15.

### DETAILED DESCRIPTION

### Assumptions

First, assumptions as a basis of an embodiment of the present disclosure will be described hereinafter.

In general, a photomask is used in an exposure device of a reduced projection type, and thus the reduction ratio of the exposure device needs to be considered when discussing a pattern size on the mask. In the following embodiment, however, in describing a pattern size on a mask in correspondence with a desired pattern (e.g., a resist pattern) to be formed, values obtained by converting the pattern size based on a reduction ratio are used, if not otherwise specified, in order to avoid confusion. Specifically, in a resist pattern with a width of 63 nm formed using a mask pattern with a width of M×63 nm in a reduced projection system of one-M^{th}, the mask pattern width and the resist pattern width are both 63 nm.

In the following embodiment, M and NA represent a reduction ratio and a numerical aperture, respectively, of a reduced projection optical system of an exposure device, and λ represents the wavelength of exposure light, if not otherwise specified. A mask pattern formed on a photomask is formed after previously determining optical conditions (M, NA, and λ) of an exposure device to be used, in view of controllability of the pattern size when the mask pattern is transferred onto, for example, a resist film. Thus, a mask pattern is not generally used in an exposure device under optical conditions different from previously determined optical conditions.

In addition, a pattern formation is assumed to be a positive resist process in which a non-exposure region of a resist serves as a resist pattern. In the case of employing a negative resist process instead of a positive resist process, a non-exposure region of a resist is removed in the negative resist process, and thus a resist pattern in the case of a positive resist process can be replaced by a space pattern.

Further, a photomask is assumed to be a transmissive mask. In the case of using a reflective mask instead of the transmissive mask, a transmissive region and a light-shielding region of the transmissive mask serve as a reflective region and a non-reflective region, respectively, and thus transmission of the transmissive mask can be replaced by reflection. Specifically, an opening or a transmissive region of the transmissive mask can be replaced by a reflective part or a reflective region, and a light-shielding part can be replaced by a non-reflective part. In addition, a region (a semi-light-shielding part) which transmits part of light in the transmissive mask can be replaced by a region (a semi-reflective part) which reflects part of light.

In the following embodiment, conditions are assumed to be as follows.

The semi-light-shielding part has a permeability of, for example, 9% with respect to exposure light, and light transmitted through the semi-light-shielding part is in the same phase as light transmitted through a transmissive part. The light-shielding part has a permeability of 0% with respect to exposure light, i.e., completely blocks exposure light.

Exposure light is light with a wavelength of 193 nm from an ArF light source, and has an NA of 1.35. As off-axis illumination, annular illumination where σ_out=0.85 and σ_in =0.57 is employed.

A dense pattern is a pattern as a group of three or more line/space patterns with a pitch of 120 nm or less. An isolated space has a line width three times or more as large as the width of each space on at least one side thereof.

The foregoing conditions are merely examples, and the present disclosure is not limited to those conditions.

### Embodiment

An embodiment of the present disclosure will be described with reference to the drawings.

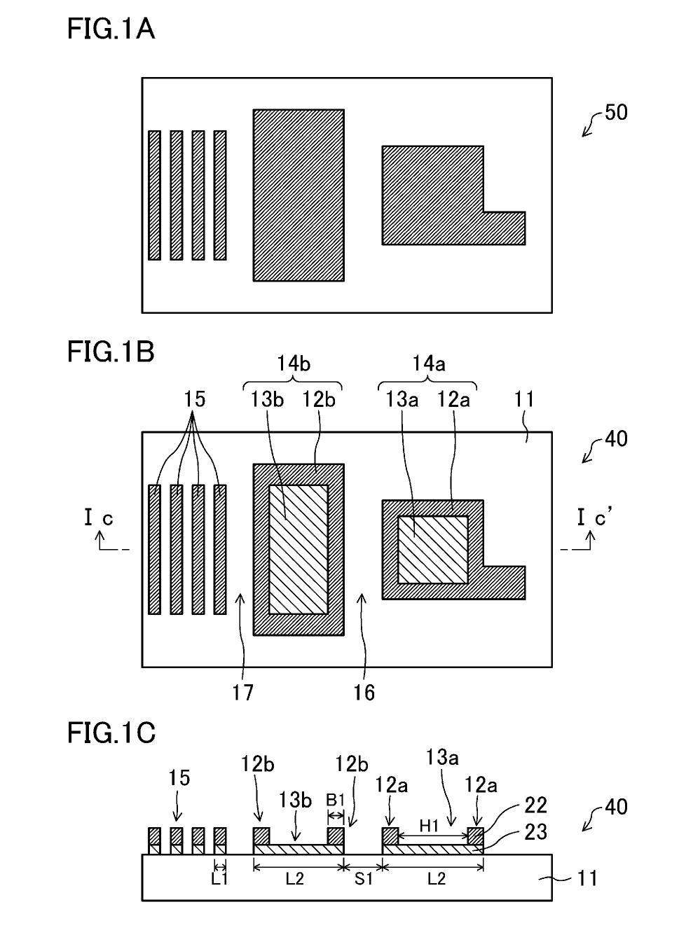

FIG. 1A is a plan view illustrating an example pattern 50 according to this embodiment. FIG. 1B is a plan view illustrating an example photomask 40 for use in formation of the pattern 50. FIG. 1C is a cross-sectional view taken along the line Ic-Ic′ in FIG. 1B.

As illustrated in FIGS. 1B and 1C, in the photomask 40, a dense mask pattern 15 having a line width L1, e.g., 60 nm, smaller than 0.7×λ/NA and mask patterns 14a and 14b each having a line width L2, e.g., 200 nm, larger than 0.7×λ/NA are provided on a transparent substrate 11 which transmits exposure light therethrough.

As illustrated in FIG. 1C, each of the dense mask pattern 15 and the mask patterns 14a and 14b has a structure in which a light-shielding film 22 is provided on a semi-light-shielding film 23. In the dense mask pattern 15, the light-shielding film 22 is provided on the entire semi-light-shielding film 23, and thus the entire the dense mask pattern 15 serves as a light-shielding part. On the other hand, in the mask patterns 14a and 14b, the light-shielding films 22 are provided on portions (mainly the outer peripheries) of the semi-light-shielding films 23, and thus semi-light-shielding parts 13a and 13b are provided in center portions of the mask patterns 14a and 14b and light-shielding parts 12a and 12b surround the semi-light-shielding parts 13a and 13b. Here, the terms of “light-shielding part” and “semi-light-shielding part” are used for structures in plan view such as FIG. 1B.

Light transmitted through the semi-light-shielding parts 13a and 13b has a phase identical to that of light transmitted through openings (i.e., portions of the transparent substrate 11 on which none of the mask patterns are provided).

An isolated space 16 is provided between the mask pattern 14a and the mask pattern 14b, and an isolated space 17 is provided between the mask pattern 14b and the dense mask pattern 15. Along the Ic-Ic′ in FIG. 1B (i.e., the line along which the two mask patterns face each other with the isolated space sandwiched therebetween), the isolated space 16 has a width S1, each of the light-shielding parts 12a and 12b has a width B1, and each of the semi-light-shielding parts 13a and 13b has a width H1.

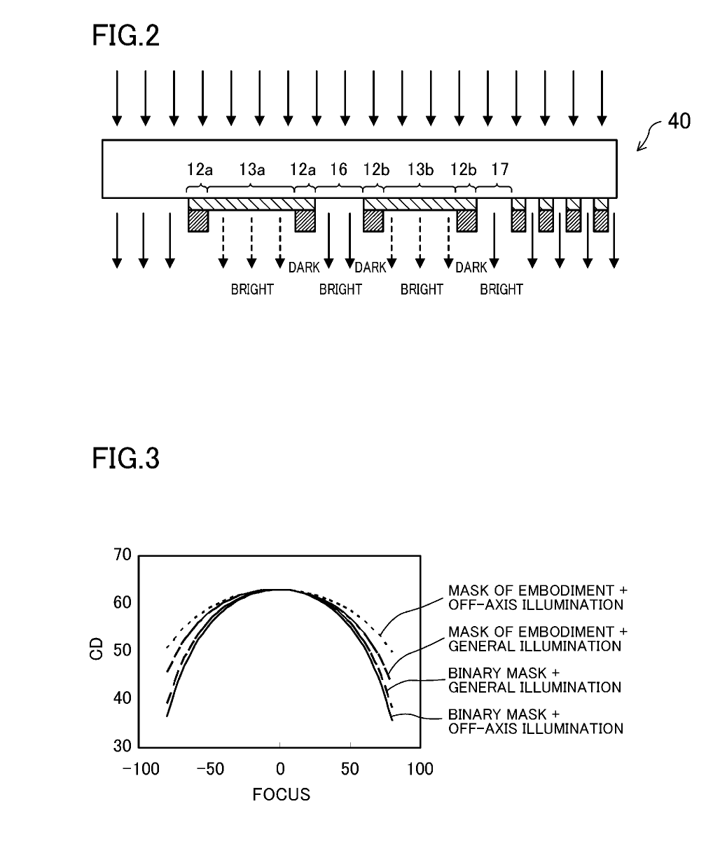

FIG. 2 is a view illustrating an image of transmitted light in exposure with the photomask 40. Light transmitted through the isolated spaces 16 and 17 and light transmitted through the semi-light-shielding parts 13a and 13b are in the same phase. As illustrated in FIG. 2, the semi-light-shielding part 13a, the light-shielding part 12a, the isolated space 16 (the opening), the light-shielding part 12b, and the semi-light-shielding part 13b are stacked in this order, thereby providing a highly periodic distribution in which optical environments around the isolated space 16 are bright, dark, bright, dark, and bright. Consequently, the DOF can be increased.

FIG. 3 shows changes in critical dimension (CD) with respect to focus variations in exposure with a mask of this embodiment including the light-shielding part and the semi-light-shielding part and a general binary mask having a pattern made of only a light-shielding part. This graph shows both of the case of general illumination (i.e., vertical illumination) and the case of off-axis illumination.

Here, the maximum width of focus having a dimensional variation of ±10 nm with respect to, for example, a 63-nm target, i.e., a size within the range of 63±10 nm, is defined as a DOF. This DOF is represented as a width of focus with a CD greater than or equal to 53 nm and less than or equal to 73 nm in FIG. 3. As shown in FIG. 3, in the case of using a binary mask, a combination with off-axis illumination has a DOF of 112 nm, and a combination with general illumination has a DOF of 117 nm. On the other hand, in the case of using the photomask 40 of this embodiment, a combination with general illumination has a DOF of 128 nm, and a combination with off-axis illumination has an DOF of 146 nm.

In this manner, the use of the photomask 40 provides a smaller CD variation with respect to a focus variation, i.e., a larger DOF, than in the case of using the binary mask.

In addition, in the case of the binary mask, the DOF is larger in a combination with general illumination than in a combination with off-axis illumination. On the other hand, in the case of the photomask of this embodiment, the DOF is larger in a combination with off-axis illumination than that in a combination with general illumination. This result shows that in using off-axis illumination for forming a fine dense pattern, an isolated space pattern can also be miniaturized at the same time. In the case of the binary mask, the use of off-axis illumination for forming a fine dense pattern reduces the DOF for an isolated space pattern, and thus it is difficult to miniaturize the isolated space pattern.

Now, light-shielding parts (12a and 12b) in the photomask 40 will be more specifically described. As the width B1 (see FIG. 1C) of the light-shielding part increases, the degree of interference of light between the semi-light-shielding part and the opening decreases, resulting in that the DOF regarding the isolated spaces (16 and 17) approaches that of a binary mask. That is, it becomes difficult to obtain advantages of an increase in DOF. Thus, to increase the DOF, it is necessary to set the width B1 of the light-shielding part to a certain value or less.

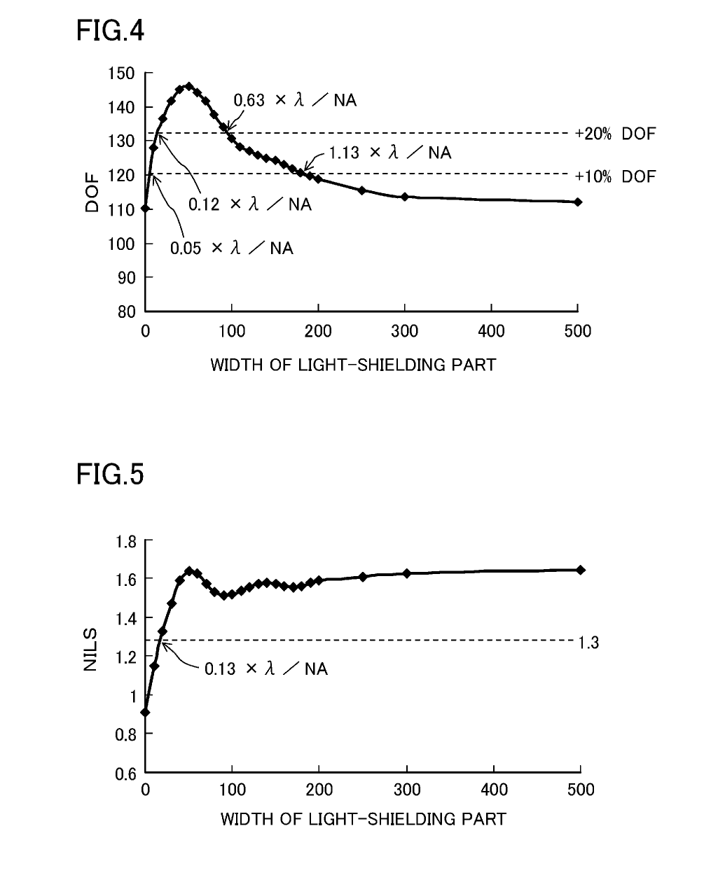

FIG. 4 shows a relationship between the width of the light-shielding part and the DOF in the isolated space. Here, as in FIG. 3, a DOF is defined as a maximum width of focus having a dimensional variation within ±10 nm with respect to, for example, a target width of 63 nm.

As shown in FIG. 4, except for a range in which the light-shielding part has an extremely small width, the width of the light-shielding part needs to be reduced in order to increase the DOF. Specifically, the width of the light-shielding part is set in the range from 0.05×λ/NA (7 nm in the example described as an assumption) to 1.13×λ/NA (161 nm in the same example), both inclusive. Then, the DOF increases by 10% or more, as compared to the binary mask. In addition, if the width of the light-shielding part is set in the range from 0.12×λ/NA (17 nm in the same example) to 0.63×λ/NA (90 nm in the same example), both inclusive, a DOF increase of 20% or more can be achieved. Likewise, it is possible to obtain a preferable range of the width B1 of the light-shielding part for a DOF increase by a desired amount based on FIG. 4.

On the other hand, if the width B1 of the light-shielding part is excessively small, the influence of introduction of light transmitted through the semi-light-shielding part on light transmitted through the isolated space (the opening) is increased. Consequently, the minimum value of light intensity associated with the isolated space does not decrease, thereby deteriorating a normalized image log slope (NILS) in the isolated space. For this reason, in view of the NILS, the width B1 of the light-shielding part needs to be set at a predetermined value or more.

The NILS is defined as follows:

NILS=(δ ln I/δx)×W

where I is a light intensity, (δ ln I/δx) is a logarithmic slope of the light intensity, and W is a size of the pattern. As the value of the NILS increases, the margin of the exposure amount to be obtained increases. In the case of a fine pattern formed by ArF light exposure, the NILS is preferably 1.3 or more, for example. If the width of the light-shielding part is reduced, the light intensity of a dark part near the opening does not decrease, and the slope of the light intensity becomes gentle. Accordingly, the NILS decreases.

FIG. 5 is a graph showing a relationship between the width B1 of the light-shielding part and the NILS in the isolated space pattern.

In a miniaturization process, the NILS is preferably 1.3 or more. FIG. 5 shows that the width B1 of the light-shielding part needs to be 0.13×λ/NA (18 nm in the example described as an assumption) or more. The width B1 of the light-shielding part necessary for obtaining a desired NILS can be obtained from FIG. 5.

In view of conditions based on the DOF and the NILS described above, the maximum value of the width B1 of the light-shielding part is determined based on the DOF, and the minimum value thereof is determined based on the NILS.

Specifically, a photomask (the photomask 40 illustrated in FIGS. 1B and 1C) in which the distance (the space distance S1) between a mask pattern having a width L2 larger than 0.7×λ/NA and its adjacent mask pattern is smaller than 0.5×λ/NA will be described as an example. In this example, the semi-light-shielding parts 13a and 13b are disposed in the mask patterns 14a and 14b each having a width L2, and the light-shielding parts 12a and 12b each having a width greater than or equal to 0.13×λ/NA and less than or equal to 1.13×λ/NA are disposed around the semi-light-shielding parts 13a and 13b. This structure ensures a sufficient NILS, and can increase the DOF in the isolated space by 10% or more. Likewise, the width of the light-shielding part greater than or equal to 0.13×λ/NA and less than or equal to 0.63×λ/NA ensures a sufficient NILS and can increase the DOF in the isolated space by 20% or more.

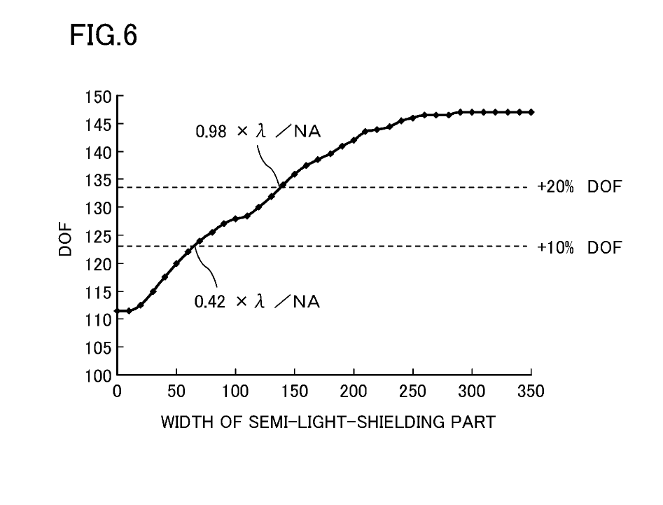

Then, the width of the semi-light-shielding part will be described. If the semi-light-shielding part has a small width, the light intensity associated with the semi-light-shielding part is smaller than that associated with the isolated space pattern during light exposure. Consequently, the periodicity of distribution of the light intensity is not sufficiently enhanced, resulting in difficulty in obtaining advantages of an increase in DOF. This phenomenon will now be described with reference to FIG. 6.

FIG. 6 shows a relationship between the width of the semi-light-shielding part and the DOF obtained by simulation. FIG. 6 shows that in a case where the width of the semi-light-shielding part is larger than 0.42×λ/NA (i.e., larger than 60 nm in the example described as an assumption), the DOF can be increased by 10%, as compared to the case of a binary mask including no semi-light-shielding part (corresponding to a case where the width of the semi-light-shielding part is 0 nm). In addition, in a case where the width of the semi-light-shielding part is larger than 0.98×λ/NA (i.e., larger than 140 nm in the example described as an assumption), the DOF can be increased by 20%, as compared to the case of a binary mask.

The width H1 of the semi-light-shielding part and the width B1 of the light-shielding part can be set larger than those in the limit of mask formation. Thus, the mask can be easily formed, and the cost can be reduced.

The specific values (e.g., a value of n in expressing a size as n×λ/NA) described above are merely examples, and the present disclosure is not limited to these values. If the wavelength of the exposure light, the shape of the light source, and/or values such as NA and M are different from those in the above example, desired values can be obtained in a similar manner.

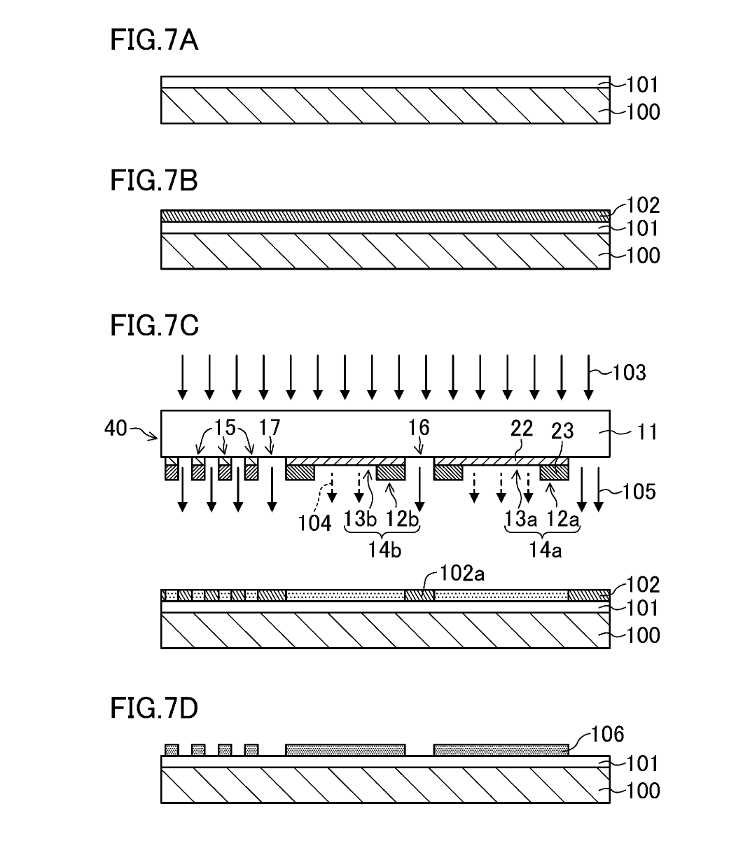

A method for forming a pattern using the photomask 40 of this embodiment will be described with reference to FIGS. 7A-7D which are cross-sectional views schematically illustrating process steps of the method.

First, as illustrated in FIG. 7A, a target film 101 such as a metal film or an insulating film is formed on a substrate 100 of, for example, silicon. Then, as illustrated in FIG. 7B, a positive resist film 102 is formed on the target film 101.

Next, as illustrated in FIG. 7C, light exposure is performed through a photomask 40. For example, exposure light 103 is applied using an ArF excimer laser or a KrF excimer laser, for example, as a light source. In this manner, the resist film 102 is exposed to light 105 transmitted through openings (e.g., isolated spaces 16 and 17, regions between dense mask patterns 15) in the photomask 40, thereby forming latent image parts 102a in portions corresponding to the openings.

Thereafter, as illustrated in FIG. 7D, development is performed to remove the latent image parts 102a, thereby obtaining a resist pattern 106 of unexposed portions of the resist film 102.

In the exposure illustrated in FIG. 7C, only the latent image parts 102a are subjected to exposure energy which is high enough to allow the resist film 102 to be completely dissolved in the development. Light 104 transmitted through the halftone parts (i.e., the semi-light-shielding parts 13a and 13b) of the photomask 40 is in the same phase as the light 105 transmitted through the openings, but does not have energy which is high enough to change the resist film 102 into an latent image part through exposure. Thus, only parts of the resist film 102 corresponding to the openings in the photomask 40 are exposed to light.

As described above, in the photomask 40, it is assumed that each of the mask patterns 14a and 14b each having a width L2 greater than 0.7×λ/NA is disposed at an interval (a space distance S1) less than or equal to 0.5×λ/NA apart from its adjacent pattern. In this assumption, a semi-light-shielding part having a width greater than 0.42×λ/NA is disposed within the pattern having a width L2, and a light-shielding part having a width greater than 0.13×λ/NA and less than 1.13×λ/NA is disposed around the semi-light-shielding part. In addition, a fine dense mask pattern 15 having a line width L1 less than 0.7×λ/NA is disposed at a space distance S1 apart from the pattern having the width L2. In this manner, in the photomask, the arrangement of openings, the light-shielding part, and the semi-light-shielding part allows distribution of the light intensity in exposure to have a periodicity such as bright, dark, bright, and dark. In addition, the dimensional relationships illustrated in FIGS. 4-6 are achieved.

Exposure employing off-axis illumination with the above photomask 40 for forming the fine dense mask pattern 15 enables an increase in DOF in, for example, the isolated space 16. As a result, both of the fine dense pattern and the isolated space pattern can be accurately formed at the same time.

### (Variations)

Variations of the photomask of the embodiment will be described.

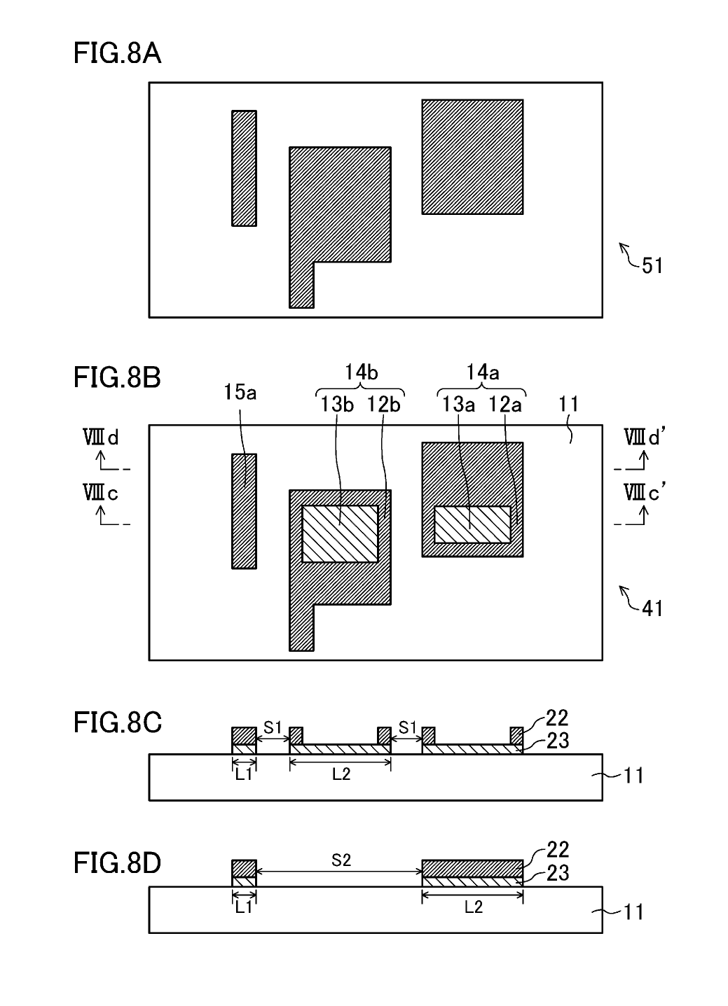

FIG. 8A is a plan view illustrating an example pattern 51 according to a variation of the embodiment. FIG. 8B is a plan view illustrating an example photomask 41 for use in formation of the pattern 51. FIG. 8C is a cross-sectional view taken along the line VIIIc-VIIIc′ in FIG. 5B. FIG. 8D is a cross-sectional view taken along the line VIIId-VIIId′ in FIG. 5B. In FIGS. 8A-8D, like reference characters are used to designate identical or equivalent elements in FIGS. 1A-1C.

In a similar manner to the photomask 40 illustrated in FIG. 1B, in the photomask 41, semi-light-shielding parts 13a and 13b are located inside mask patterns 14a and 14b, and light-shielding parts 12a and 12b are provided around the semi-light-shielding parts 13a and 13b. The mask patterns 14a and 14b each having a width L2 are disposed along the line Vc-Vc′ (i.e., the line along which the mask patterns face each other with the isolated space sandwiched therebetween), and are spaced from each other at a space distance 51.

However, along the line VIIId-VIIId′ different from the line VIIId-VIIId′, the mask pattern 14a and the mask pattern 14b are not disposed side by side, and the mask pattern 14a is located at the side of the mask pattern 15a with a space distance S2 greater than 0.5×λ/NA×M. In this manner, a portion of the mask pattern 14a is located apart from the adjacent mask pattern at a distance greater than a predetermined value (i.e., a value determined based on λ, NA, and M, such as 0.5×λ/NA×M described above). In this portion of the mask pattern 14a, the semi-light-shielding part 13a is not disposed.

Similarly, in the mask pattern 14b, the semi-light-shielding part 13b is disposed in a portion of the mask pattern 14b located apart from the mask pattern 14a at the space distance S1.

That is, in the isolated space with the space distance S1 having an insufficient DOF, the semi-light-shielding part is located within the mask pattern, whereas in the isolated space with the space distance S2 which does not need an increase in DOF, no semi-light-shielding part is disposed. With this structure, it is possible to increase the DOF in a portion which needs a DOF increase. In addition, the photomask can be easily processed, and the drawing time can be shortened, thereby reducing the cost for the mask.

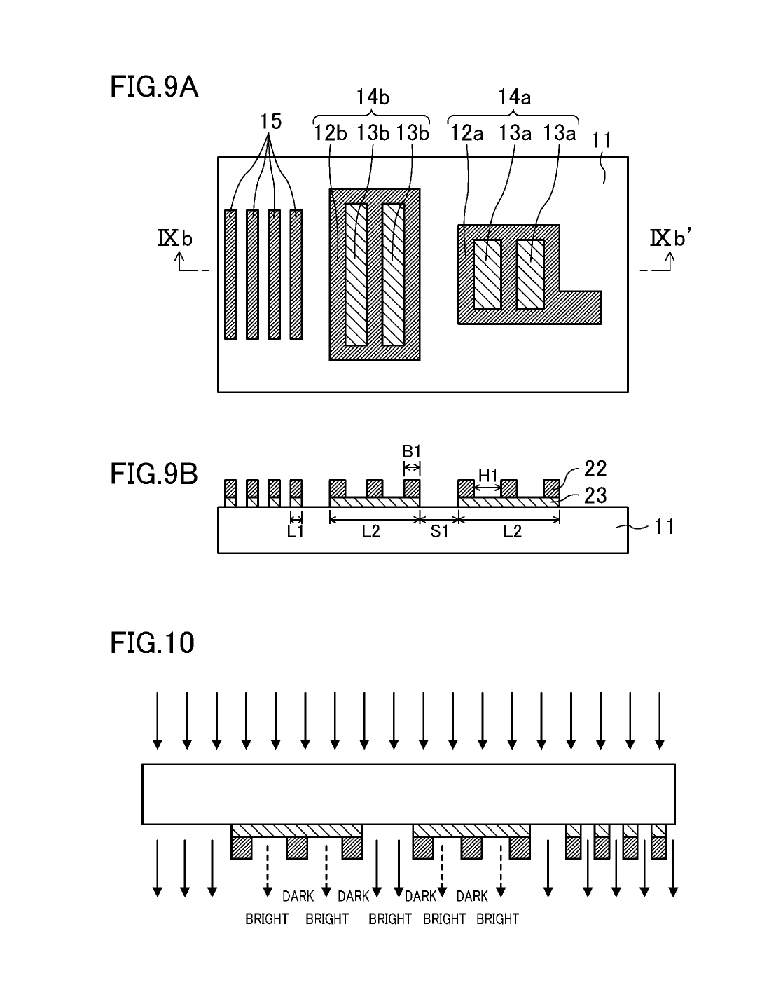

FIG. 9A is a plan view illustrating another example photomask 42. The photomask 42 has a pattern for forming the pattern illustrated in FIG. 1A. FIG. 9B is a cross-sectional view taken along the line IXb-IXb′ in FIG. 9A.

In the case of the photomask 40 illustrated in FIG. 1B, the light-shielding parts 12a and 12b are disposed in the peripheries of the mask patterns 14a and 14b, and each of the semi-light-shielding parts 13a and 13b is formed as a continuous region. On the other hand, in the case of the photomask 42 illustrated in FIG. 9A, the light-shielding parts 12a and 12b are also formed inside the mask patterns 14a and 14b, and divide the semi-light-shielding parts 13a and 13b into multiple portions.

Exposure with this photomask 42 can further enhance the periodicity, such as bright, dark, bright, and dark, in distribution of the light intensity, as illustrated in FIG. 10. Thus, the DOF in the isolated space can be further increased.

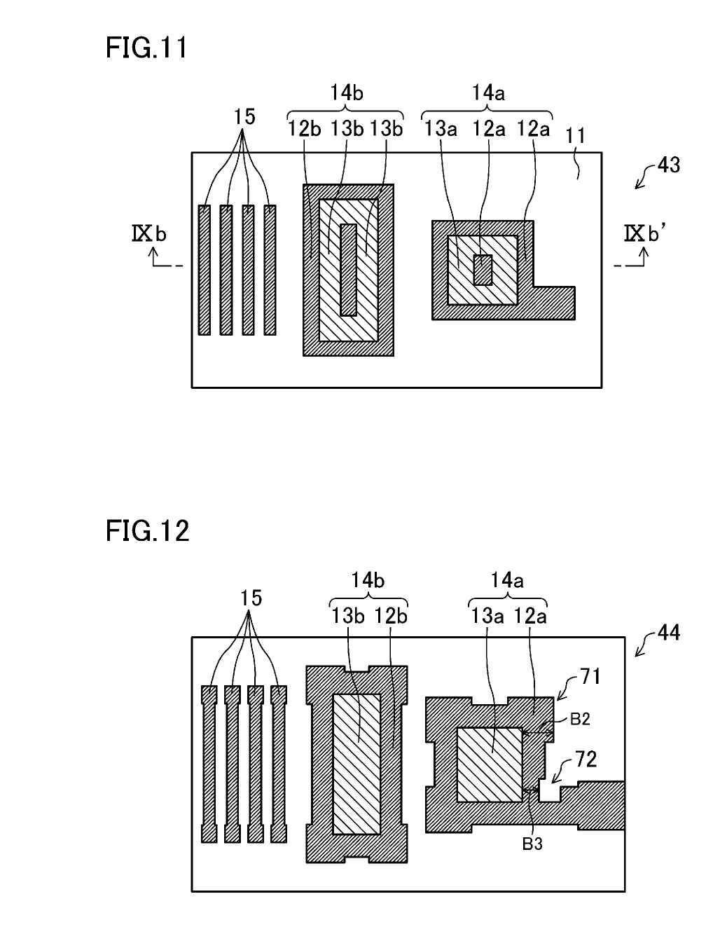

FIG. 11 illustrates another example photomask 43 for use in formation of the pattern illustrated in FIG. 1A. In the case of the photomask 43, the light-shielding parts 12a and 12b are disposed not only in the peripheries of the mask patterns 14a and 14b but also inside the semi-light-shielding parts 13a and 13b to form island shapes. In this case, the cross-sectional structure taken along the line IXb-IXb′ in FIG. 11 are similar to that illustrated in FIG. 9B. Thus, exposure with the photomask 43 can enhance the periodicity of bright and dark in distribution of the light intensity, thereby achieving an increase in DOF.

Alternatively, semi-light-shielding parts and light-shielding parts may be alternatively arranged along the line in which mask patterns face each other with an isolated space pattern sandwiched therebetween (e.g., along the line IXb-IXb′ in FIG. 9A), In this structure, the DOF can also be increased. A portion of a light-shielding part surrounding a semi-light-shielding part may have a projection which does not reach the opposite light-shielding part.

FIG. 12 illustrates another example photomask 44 for use in formation of the pattern illustrated in FIG. 1A. The photomask 44 is the same as the photomask 40 illustrated in FIG. 1B in that the light-shielding parts 12a and 12b are disposed in the peripheries of the mask patterns 14a and 14b. However, each of the light-shielding parts 12a and 12b surrounding the semi-light-shielding parts 13a and 13b has a width B2 at a projecting corner 71 in plan view greater than a width B3 at a recessed corner 72. This structure considers optical proximity correction (OPC). The mask pattern with such a structure can improve the shape (i.e., ensure a rectangular shape) of the pattern after being transferred. The dense mask pattern 15 has large widths at both ends thereof for the same reason.

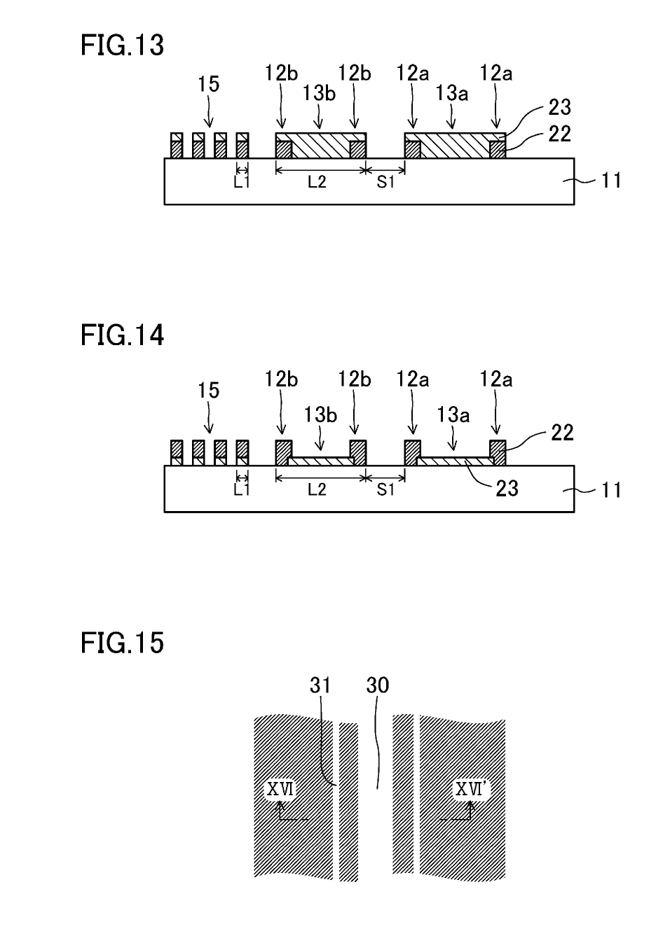

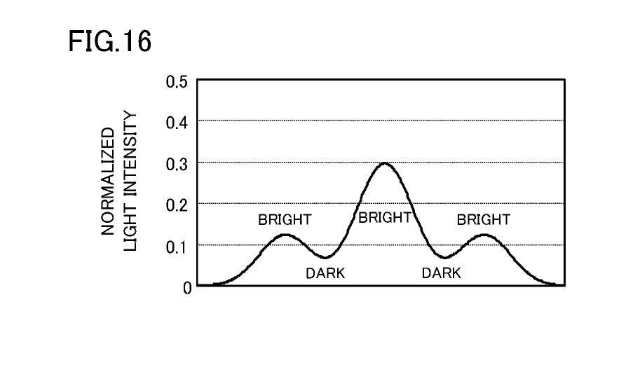

FIGS. 13 and 14 are cross-sectional views schematically illustrating other examples of arrangement of the semi-light-shielding parts and the light-shielding parts.

In the case of the photomask 40 illustrated in FIG. 1C, the semi-light-shielding film 23 is formed on the transparent substrate 11, and the light-shielding film 22 is formed on necessary portions of the semi-light-shielding film 23, thereby forming the semi-light-shielding parts 13a and 13b and the light-shielding parts 12a and 12b.

On the other hand, in the example illustrated in FIG. 13, the light-shielding film 22 is formed on necessary portions of the transparent substrate 11, and the semi-light-shielding film 23 is formed on necessary portions of the transparent substrate 11 to cover the light-shielding film 22, thereby forming the semi-light-shielding parts 13a and 13b and the light-shielding parts 12a and 12b.

In the example illustrated in FIG. 14, the semi-light-shielding film 23 is patterned to remain on necessary portions of the transparent substrate 11, and the light-shielding film 22 is formed on the remaining portions of the semi-light-shielding film 23 and necessary portions the transparent substrate 11, thereby forming the semi-light-shielding parts 13a and 13b and the light-shielding parts 12a and 12b. In the example illustrated in FIG. 1C, the side surfaces of the semi-light-shielding film 23 and the light-shielding film 22 are flush with each other, whereas in the example illustrated in FIG. 14, the light-shielding film 22 covers the side surface of the semi-light-shielding film 23 and is partially in contact with the upper surface of the transparent substrate 11.

In either example, irrespective of the semi-light-shielding film 23, portions corresponding to the light-shielding film 22 serve as the light-shielding parts. Thus, in FIG. 14, the width of the light-shielding part is a range extending from an edge of the light-shielding part facing the space pattern to the opposite edge.

The light-shielding part and the semi-light-shielding part in the photomask may be arranged as illustrated in FIGS. 13 and 14. In these examples, the DOF in the isolated space pattern can be increased by setting the width of the light-shielding part at a predetermined value (e.g., greater than 0.13×λ/NA and less than 1.13×λ/NA) as described above.

A photomask according to the present disclosure and a pattern formation method using the photomask enable a dense pattern and an isolated space pattern to be accurately formed at the same time without formation of a side lobe, and also enables easy formation of the photomask. Thus, the present disclosure is useful for pattern formation in a process in which both an SRAM region (a dense pattern) and a logic region (an isolated space pattern) regarding, for example, transistor isolation are present at the same time.

What is claimed is:

1. A photomask, comprising:
a transparent substrate; and
first and second mask patterns located on the transparent substrate and at least partially facing each other with a space sandwiched therebetween, wherein
the first mask pattern includes a semi-light-shielding part which transmits part of light therethrough and a light-shielding part,
in the first mask pattern, the semi-light-shielding part at least partially faces the space with the light-shielding part sandwiched therebetween,
in a direction along which the first mask pattern and the second mask pattern face each other,
the first mask pattern has a size greater than (0.7×λ/NA)×M, and
the space has a size less than or equal to (0.5×λ/NA)×M (where λ is a wavelength of exposure light, NA is a numerical aperture of a reduced projection optical system of an exposure device, and M is a magnification of the reduced projection optical system).

2. The photomask of claim 1, wherein
the second mask pattern includes a semi-light-shielding part which transmits part of light therethrough and a light-shielding part, and
in the second mask pattern, the semi-light-shielding part faces the space with the light-shielding part sandwiched therebetween.

3. The photomask of claim 2, wherein
in a direction along which the first mask pattern and the second mask pattern face each other, the second mask pattern has a size greater than (0.7×λ/NA)×M.

4. The photomask of claim 1, wherein
in a direction along which the first mask pattern and the second mask pattern face each other, a size of the light-shielding part and a size of the semi-light-shielding part are determined based on λ, Na, and M (where λ is a wavelength of exposure light, NA is a numerical aperture of a reduced projection optical system of an exposure device, and M is a magnification of the reduced projection optical system).

5. The photomask of claim 4, wherein
the light-shielding part has a size greater than or equal to (0.13×λ/NA)×M.

6. The photomask of claim 4, wherein
the light-shielding part has a size less than or equal to (1.13×λ/NA)×M.

7. The photomask of claim 4, wherein
the semi-light-shielding part has a size greater than or equal to (0.42×λ/NA)×M.

8. The photomask of claim 1, wherein
light transmitted through the semi-light-shielding part has a phase identical to that of light transmitted through the space.

9. The photomask of claim 1, wherein
the light-shielding part surrounds the semi-light-shielding part.

10. The photomask of claim 9, wherein
a width of the light-shielding part at a projecting corner of the first mask pattern is larger than that at a recessed corner of the first mask pattern.

11. The photomask of claim 1, wherein
the semi-light-shielding part is divided into a plurality of portions by the light-shielding part.

12. The photomask of claim 1, wherein
the light-shielding part is partially sandwiched between the semi-light-shielding parts of the first and second mask patterns in a direction along which the first mask pattern and the second mask pattern face each other.

13. The photomask of claim 1, wherein
the semi-light-shielding part has a light transmittance with which an intensity of light transmitted through the semi-light-shielding part is lower than that at which an exposure region is formed.

14. The photomask of claim 1, wherein
the semi-light-shielding part is located only in a region facing the space with the light-shielding part sandwiched therebetween.

15. The photomask of claim 1, wherein
the second mask pattern includes a light-shielding part, and
in a direction along which the first mask pattern and the second mask pattern face each other, the second mask pattern has a size less than or equal to (0.7×λ/NA)×M.

16. A pattern formation method using the photomask of claim 1, the method comprising:
forming a resist film on a substrate;
irradiating the resist film with exposure light through the photomask; and
developing the resist film irradiated with the exposure light, and then patterning the resist film.

17. The pattern formation method of claim 16, wherein
the irradiating the resist film employs off-axis illumination.

18. A photomask, comprising:
a reflective substrate; and
first and second mask patterns located on the reflective substrate and at least partially facing each other with a space sandwiched therebetween, wherein
the first mask pattern includes a semi-reflective part which reflects part of light and a non-reflective part which reflects substantially no light,
in the first mask pattern, the semi-reflective part faces the space with the non-reflective part sandwiched therebetween,
in a direction along which the first mask pattern and the second mask pattern face each other,
the first mask pattern has a size greater than (0.7×λ/NA)×M, and
the space has a size less than or equal to (0.5×λ/NA)×M (where λ is a wavelength of exposure light, NA is a numerical aperture of a reduced projection optical system of an exposure device, and M is a magnification of the reduced projection optical system).

19. A pattern formation method using the photomask of claim 18, the method comprising:
forming a resist film on a substrate;
irradiating the resist film with exposure light through the photomask; and
developing the resist film irradiated with the exposure light, and then patterning the resist film.

20. The pattern formation method of claim 19, wherein
the irradiating the resist film employs off-axis illumination.
